(19) United States
(12) Patent Application Publication
(10) Pub. No.: US 2015/0060527 A1
(43) Pub. Date: Mar. 5, 2015

(54) NON-UNIFORM HEATER FOR REDUCED TEMPERATURE GRADIENT DURING THERMAL COMPRESSION BONDING

(71) Applicants: Weihua Tang, Chandler, AZ (US); Sung-Won Moon, Phoenix, AZ (US); Sangil Lee, Chandler, AZ (US)

(72) Inventors: Weihua Tang, Chandler, AZ (US); Sung-Won Moon, Phoenix, AZ (US); Sangil Lee, Chandler, AZ (US)

(21) Appl. No.: 14/013,626

(22) Filed: Aug. 29, 2013

(51) Int. Cl. H01L 23/00; B23K 31/02; H05B 3/00; B23K 1/00

(52) U.S. Cl. CPC H01L 24/81; B23K 1/0016; B23K 31/02; H05B 3/0014; H01L 24/75; B23K 2201/40; H01L 2224/81204; H01L 2224/81801; H01L 2224/753; H01L 2224/75253; H01L 2224/75264
USPC 228/180.22; 219/552

(57) ABSTRACT

Embodiments of a method for performing a thermal compression bonding process with a non-uniform temperature pattern and a heater having the non-uniform temperature pattern are disclosed. In some embodiments, the heater includes a plurality of heating element segments configured to generate the non-uniform temperature pattern. The configuration comprises a plurality of heating element segment densities or a plurality of heating element segment resistances.

### TECHNICAL FIELD

Embodiments described herein generally relate to thermal compression bonding. Some embodiments relate to a non-uniform heater used during thermal compression bonding of integrated circuit dies.

### BACKGROUND

Integrated circuit dies may be attached to substrates or circuit boards using a process commonly referred to in the art as thermal compression bonding. Solder balls may be attached to various points of the die that are desired to be anchored to the substrate. The die may then be heated to melt the solder balls and the die and substrate are compressed such that, when the solder balls cool, the die may be attached to the substrate.

A heater may be used during a fabrication process to heat the die, substrate, and solder balls in order to perform the bonding. One problem that may occur with present heaters is that the edges and/or corners of the die/substrate combination are more exposed to ambient air temperatures than the remainder of the die/substrate combination creating a relatively large temperature gradient across the die/substrate combination. Thus, some areas of the die/substrate combination may be cooler than other areas. The cooler areas may not be hot enough to melt the solder balls.

In order to compensate for this large temperature gradient across the die/substrate combination, the overall temperature of the heater may be increased such that the edges and/or corners of the die/substrate combination are at a temperature that is adequate for properly melting the solder balls. However, this also increases the temperature of the inner portions of the die/substrate combination such that the inner portion is now hotter than is typically used to accomplish the task of melting the solder balls. This may result in yield loss from solder bridging on inner portions.

Since the solder balls attached to the inner portion of the die may be heated to a much greater temperature than its melting temperature, they may have a longer cool down time as well. The relatively large temperature gradient across the die/substrate combination may thus lead to longer fabrication times as well as negatively impact the solder ball joint quality.

There are general needs for reducing the temperature gradient across a die/substrate combination during a thermal compression bonding process.

### BRIEF DESCRIPTION OF THE DRAWINGS

FIG. 1 illustrates a diagram of an embodiment of a non-uniform heater concept.

FIG. 2 illustrates a diagram of an embodiment of a non-uniform heater with heating elements.

FIGS. 3A-3C illustrate cross-sectional views of an embodiment of a thermal compression bonding process in accordance with the embodiments of FIGS. 1 and 2.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

A relatively large temperature gradient across an integrated circuit die and substrate during a thermal compression bonding process may result in various problems. For example, a higher temperature in certain areas of the die/substrate combination may result in reduced solder joint quality as well as a slower bonding process since the hotter solder balls take longer to cool and solidify.

A heater that generates a non-uniform temperature pattern may be used to reduce the relatively large temperature gradient across the die/substrate combination. Since edges and/or corners of the die/substrate combination may be cooler due to cooling by ambient air temperatures, a heater with a non-uniform heat pattern may heat these areas of the die/substrate combination differently such that an inner portion of the die/substrate combination is heated by a lower temperature than an outer portion of the die/substrate combination. This may be accomplished by different densities of heating element segments on the heater or different resistances for the heating element segments.

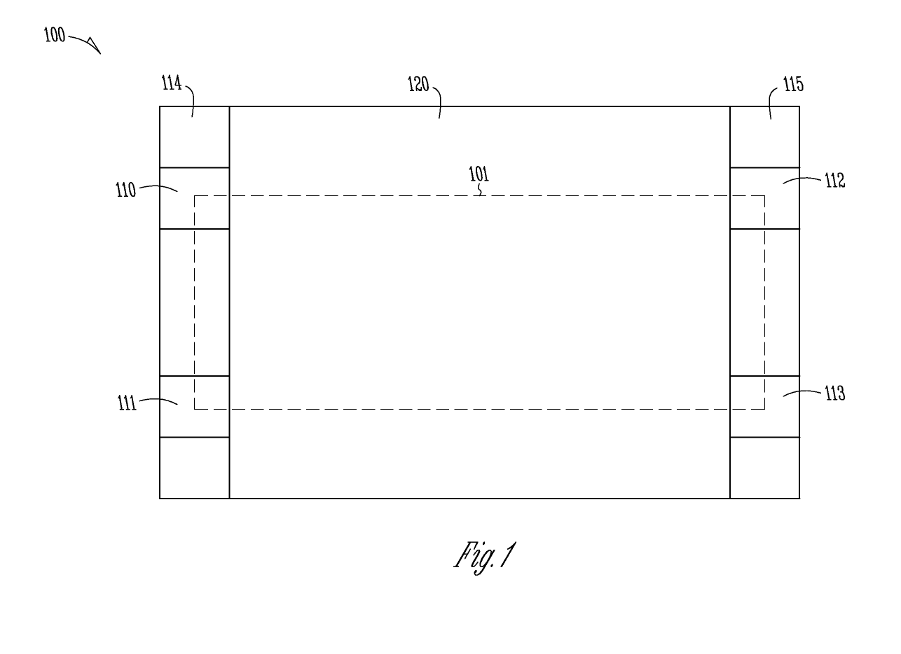

FIG. 1 illustrates a diagram of an embodiment of a non-uniform heater concept. This diagram illustrates how a heater may be configured to generate a non-uniform temperature output in order to reduce a relatively large temperature gradient resulting from the heating of a die/substrate combination during a thermal compression bonding process. The diagram of FIG. 1 is for purposes of illustration only as different thermal compression bonding process embodiments may use different configurations for a non-uniform heater.

The heater 100 is shown with an outline of a typical die 101 located over the heater 100. As described previously, the edges and corners of the die 101 and/or substrate (not shown) may be cooler during the thermal compression bonding process due to the proximity of these areas to the cooler ambient air. Thus, certain areas 110-115 of the heater 100 associated with the edges and corners of the die 101 may be configured to generate a higher temperature than the remainder 120 of the heater 100.

The non-uniform heater concept is shown in FIG. 1 having multiple areas 110-115, 120 with different temperatures. For example, the corners of a die 101 may experience the most ambient cooling due to both sides of the die 101 being exposed to the cooler ambient air. Thus, the areas 110-113 of the heater 100 associated with the corners of the die 101 may generate the highest temperatures of the heater 100.

Each edge of the die 101 may experience less cooling than the corners but may still experience greater cooling than the remainder of the die. Thus, certain areas 114, 115 of the heater 100 associated with the edges of the die 101 may generate temperatures that are less than the corner areas 110-113 but still higher than the remainder 120 of the heater 100.

FIG. 1 shows only the areas 114, 115 of the heater 100 associated with the vertical edges of the die as generating a relatively higher temperature. Another embodiment may also generate relatively higher temperatures along areas of the heater 100 associated with the horizontal edges of the die along with the vertical edges. Another embodiment may generate relatively higher temperatures only along areas of the heater associated with the horizontal edges of the die.

As shown in FIG. 1, the size of the heater 100 may also be relatively larger than the size of the die 101. This may extend the heating of the die 101 beyond the edges of the die 101 and, thus, reduce the cooling caused by interaction of the corners and edges of the die 101 with the ambient air.

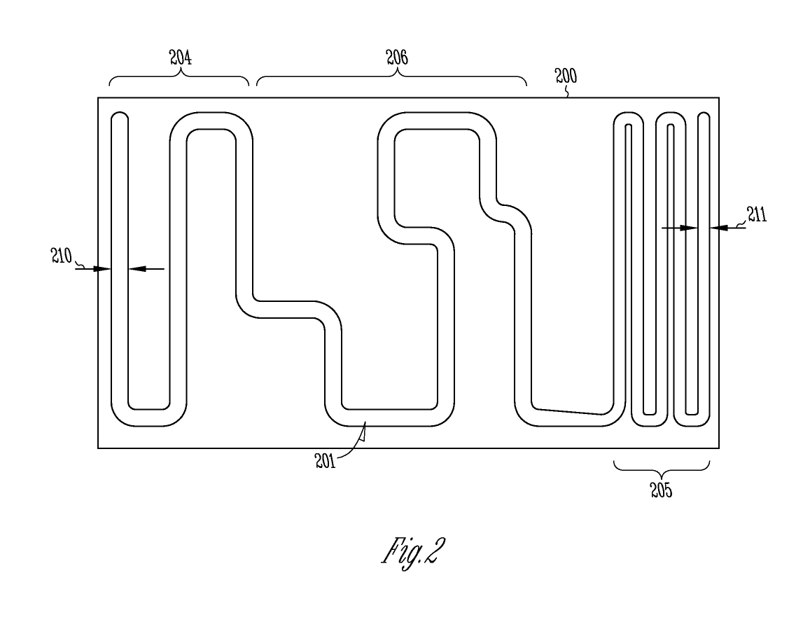

FIG. 2 illustrates a diagram of an embodiment of a non-uniform heater 200 with a heating element 201. The diagram of FIG. 2 illustrates different methods for generating a non-uniform temperature pattern across the surface of the thermal compression bonding heater.

One illustrated method for generating a non-uniform temperature pattern may use different distances between multiple segments of the heating element 201. For example, the segments of the heating element 201 in end portions 204, 205 near the vertical edges of the heater 200 are closer together than the heating element 201 segments in the central portion 206 of the heater 200. Placing the heating element 201 segments closer together may generate a higher temperature in those portions 204, 205 of the heater 200 than the temperature generated in the central portion 206 where the segments are further apart.

Another illustrated method for generating a non-uniform temperature pattern may use different cross sectional areas of the heating element 201. As illustrated in FIG. 2, the heating element 201 segments in the end portion 205 near the right vertical edge of the heater have a smaller cross sectional area and/or depth than heating element 201 segments in inner portions 204, 206 of the heater 200. The smaller cross sectional area may increase the resistance of the segments in that particular portion 205. An increased resistance may result in an increased heat generated and, thus, an increased temperature for those particular traces.

Referring to FIG. 2, the central portion 206 and left end portion 204 of the heater 200 of FIG. 2 may generate less heat than the right end portion 205 of the heater 200. Since the right end portion 205 comprises heating element 201 segments having both a smaller cross sectional area 211 as well as being placed closer together, the right end portion 205 may generate the highest temperature of the heater 200. The left end portion 204 may generate the next highest temperature as a result of the heating element 201 segments being placed closer together than the central portion 206 but having the same cross sectional area 210 as the segments of the central portion. The central portion 206 may generate the lowest temperature of the heater 200 as a result of the segments having a larger cross sectional area and also being placed further apart than the other portions 204, 205 of the heater 200 (i.e., having a larger element pitch). Pitch may be defined as a distance between the various segments of the heating element 201.

Another method for generating a non-uniform temperature pattern may use different chemical compositions for different segments of the heating element 201. Different chemical compositions for different segments of the heating element 201 may change the resistance of the heating element 201 in those areas of the heater 200. A predetermined temperature, in a particular portion 204-206 of the heater 200, may thus be generated by a predetermined resistance in that particular portion 204-206.

For example, a heating element 201 may typically include a pure metal, a metal alloy, or a paste-like material. For example, the heating element 201 may include gold (Au), copper (Cu), or tungsten/alumina (W/ALN). Introducing different compositions into different segments of the heating element may change the resistance in those segments.

Thus, referring to FIG. 2, if it is desired to increase the temperature generated in the left end portion 204 of the heater 200, metal alloy of higher resistivity may be introduced into the segments of that portion 204 of the heater 200 while the remaining heating element 201 segments may consist of metal alloy of lower resistivity.

Additional examples for increasing the temperature of the heater 200 in a non-uniform manner may include a constant pitch and constant heating element 201 cross-sectional area in portions 204-206 having different chemical compositions; a constant chemical composition, varied pitch, and constant heating element 201 cross sectional area; and a constant chemical composition, constant pitch, and varied heating element 201 cross sectional area.

The embodiments of FIG. 2 for increasing the temperature of the heater 200 in a non-uniform manner are for purposes of illustration only. Other embodiments may use various combinations of these methods. Still other embodiments may use different methods for generating a non-uniform temperature pattern.

For example, the illustrated embodiment shows only a single, continuous heating element 201 that is formed into multiple segments to generate non-uniform temperatures on the heater. In such an embodiment, power is applied to only the single, continuous heating element 201.

Another embodiment may have multiple, separate heating elements where each heating element is a separate segment to generate the non-uniform temperatures on the heater. In such an embodiment, each separate segment may be powered separately such that increasing the power to one segment to increase its temperatures would not affect the power applied to any of the other segments nor the temperatures generated by those segments.

Examples to illustrate the non-uniform heating of the different portions 204-206 may include the left end portion 204 having an average output power of 1×10⁶ W/m², the center portion 206 having an average output power of 7×10⁵ W/m², and the right portion 205 having an average output power of 3×10⁶ W/m². These values for average output power are for purposes of illustration only as other embodiments may have different average output powers.

As another example of the non-uniform heating of the different portions 204-206 may be illustrated by comparisons of each portion to another portion. For example, the left portion 204 may have a first coil density, the right portion 205 may have a second coil density, and the third portion 206 may have a third coil density. It can be seen that the first coil density is less dense than the second coil density such that the two portions 204, 205 taken together have a non-uniform coil density. It can also be seen the second coil density is more dense than either of the first or the third coil densities. Thus the two portions 204, 206 taken together have a non-uniform coil density.

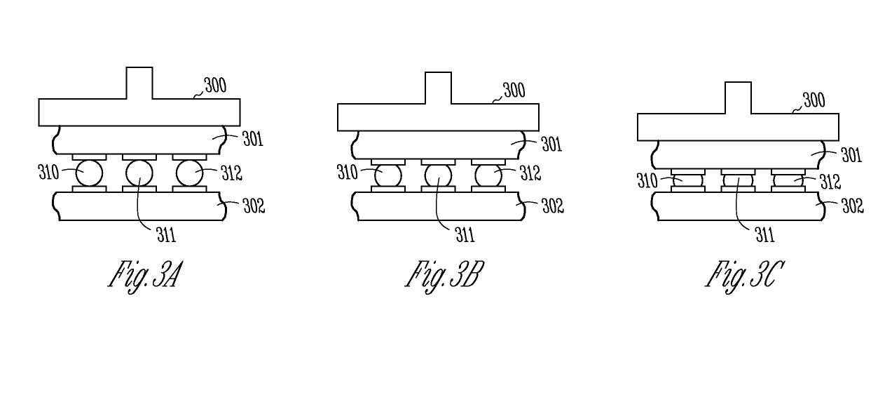

FIGS. 3A-3C illustrate cross-sectional views of an embodiment of a thermal compression bonding process in accordance with the embodiments of FIGS. 1 and 2. FIG. 3A illustrates a die 301 to be attached to a substrate 302 by a thermal compression bonding process using a non-uniform heater 300 as discussed previously. The die 301 may have the solder balls 310-312 attached and positioned over the substrate 302 using a vacuum force through one or more vacuum ports (not shown) in the heater to temporarily hold the die 301 to the heater 300.

The die 301 may be attached to the substrate 302 by a plurality of solder balls 310-312. The non-uniform heater 300 may be used to generate a non-uniform temperature pattern such that the solder balls 310-312 melt and cool at a substantially uniform rate.

FIG. 3B illustrates a mid-point at which the heater 300 has heated the solder balls 310-312 to their melting point and a compression force has begun to push the die 301 and the substrate 302 together.

FIG. 3C illustrates the final step during which the solder balls 310-312 may now be fully compressed and cooling at a substantially uniform rate. The die 301 may now be attached to the substrate 302.

In the interest of simplicity, the solder used in the present embodiments may be referred to as solder balls. However, the solder is not limited to a spherical shape. The solder may have any of one or more different shapes including spherical.

While the above disclosure refers to die-to-substrate bonding, the disclosed heater is not limited to such an embodiment. The non-uniform heater may operate to bond any apparatus to any other apparatus as well as embodiments using a non-uniform temperature pattern to heat an apparatus without bonding.

Bonding examples might include die-to-die bonding, die-to-substrate bonding, wafer-to-substrate bonding, substrate-to-substrate bonding, as well as other types of bonding.

### EXAMPLES

The following examples pertain to further embodiments.

Example 1 is a method for performing a thermal compression bonding process having a non-uniform temperature pattern. The method comprising positioning a first apparatus, coupled to a plurality of solder balls, over a second apparatus; heating the plurality of solder balls with a heater comprising the non-uniform temperature pattern wherein an outer portion of the first apparatus is heated to a higher temperature than an inner portion of the first apparatus; and compressing the first apparatus towards the second apparatus after the plurality of solder balls have melted.

In Example 2, the subject matter of Example 1 can optionally include heating the plurality of solder balls by: heating corners of the first apparatus to a first temperature; heating edges of the first apparatus to a second temperature; and heating a central portion of the first apparatus to a third temperature wherein the first temperature is greater than the second temperature which is greater than the third temperature.

In Example 3, the subject matter of Examples 1-2 can optionally include heating the plurality of solder balls with a heater comprising the non-uniform temperature pattern wherein the outer portion of the first apparatus is heated to a higher temperature than the inner portion of the first apparatus comprises heating outside edges of the first apparatus to the higher temperature than the inner portion of the first apparatus.

In Example 4, the subject matter of Examples 1-3 can optionally include wherein heating the plurality of solder balls comprises: heating portions of a thermal compression bonding heater associated with corners of the first apparatus to a first temperature; heating portions of the thermal compression bonding heater associated with edges of the first apparatus to a second temperature; and heating portions of the thermal compression bonding heater associated with a central portion of the first apparatus to a third temperature, wherein the first temperature is greater than the second temperature which is greater than the third temperature.

In Example 5, the subject matter of Examples 1-4 can optionally include wherein heating the plurality of solder balls comprises generating a plurality of different temperatures across a surface of the thermal compression bonding heater in response to a cross sectional area of heating element segments in each portion of the thermal compression bonding heater.

In Example 6, the subject matter of Examples 1-5 can optionally include wherein heating the plurality of solder balls comprises generating a plurality of different temperature across a surface of the thermal compression bonding heater in response to a pitch of heating element segments in each portion of the thermal compression bonding heater.

In Example 7, the subject matter of Examples 1-6 can optionally include wherein heating the plurality of solder balls comprises generating a plurality of different temperature across a surface of the thermal compression bonding heater in response to a chemical composition of heating element segments in each portion of the thermal compression bonding heater.

In Example 8, the subject matter of Examples 1-7 can optionally include wherein heating the plurality of solder balls comprises generating a plurality of different temperature across a surface of the thermal compression bonding heater in response to one or more of a chemical composition of heating element segments, a pitch of heating element segments, and/or a cross sectional area of heating elements segments in each portion of the thermal compression bonding heater.

Example 9 is a heater having a non-uniform temperature pattern. The heater comprising a plurality of heating element segments configured to generate the non-uniform temperature pattern, wherein the configuration comprises one of: a plurality of heating element segment densities or a plurality of heating element segment resistances.

In Example 10, the subject matter of Example 9 can optionally include wherein the plurality of heating element segments comprise a single, continuous heating element.

In Example 11, the subject matter of Examples 9-10 can optionally include wherein the plurality of heating element segments comprise a plurality of discontinuous heating element segments.

In Example 12, the subject matter of Examples 9-11 can optionally include wherein each of the plurality of discontinuous heating element segments is configured to be powered separately from the remaining discontinuous heating element segments.

In Example 13, the subject matter of Examples 9-12 can optionally include wherein the heater further comprises a plurality of portions, each of the plurality of portions having a different heating element segment density of the plurality of heating element segment densities in response to a predetermined temperature to be generated by that portion.

In Example 14, the subject matter of Examples 9-13 can optionally include wherein the heater further comprises a plurality of portions, each of the plurality of portions comprising a heating element segment having a predetermined heating element segment resistance of the plurality of heating element segment resistances than heating element segments in other portions of the plurality of portions, the predetermined resistance determined in response to a predetermined temperature to be generated by that portion.

In Example 15, the subject matter of Examples 9-14 can optionally include wherein the resistance of a heating element segment is determined in response to a composition of the heating element segment.

In Example 16, the subject matter of Examples 9-15 can optionally include wherein the resistance of a heating element segment is determined in response to a cross sectional area of the heating element segment.

Example 17 is a heater having a non-uniform temperature pattern. The heater comprising a plurality of portions, each portion having a predetermined density of heating element segments wherein each density of heating element segments is determined in response to a temperature to be generated by an associated portion.

In Example 18, the subject matter of Example 17 can optionally include wherein the plurality of portions comprise a central portion having a lower density of heating element segments than other portions of the plurality of portions.

In Example 19, the subject matter of Examples 17-18 can optionally include wherein the plurality of portions comprise first and second end portions that have a higher density of heating element segments than other portions of the plurality of portions.

In Example 20, the subject matter of Examples 17-19 can optionally include wherein the density of heating element segments in each portion is determined in response to a distance of each heating element segment from other heating element segments in each portion.

In Example 21, the subject matter of Examples 17-20 can optionally include wherein a higher density of heating element segments within a portion of the plurality of portions is configured to generate a higher temperature by the portion.

Example 22 is a heater having a non-uniform temperature pattern. The heater comprising a plurality of portions, each portion having a heating element segment comprising a different predetermined resistance, wherein each predetermined resistance is determined in response to a temperature to be generated by an associated portion.

In Example 23, the subject matter of Example 22 can optionally include wherein the predetermined resistance of a first portion of the plurality of portions is determined by a chemical composition of the heating element segment associated with the first portion.

In Example 24, the subject matter of Examples 22-23 can optionally include wherein the predetermined resistance of a second portion of the plurality of portions is determined by a cross sectional area of the heating element segment associated with the second portion.

In Example 25, the subject matter of Examples 22-24 can optionally include wherein a first portion, having a first heating element segment comprising a higher resistance than a second heating element segment in a second portion, is configured to generate a higher temperature than the second portion.

In Example 26, the subject matter of Examples 22-25 can optionally include wherein the heater comprises a size that is larger than a size of an integrated circuit die configured to be heated by the heater.

Example 27 is a method for making a thermal compression bonding heater having a non-uniform temperature pattern. The method comprising forming a heating element, comprising a plurality of heating element segments, on a surface of the heater, wherein a temperature of each portion of a plurality of portions of the surface of the heater is set in response to one or more of: a density of heating element segments in an associated portion and/or a resistance of each heating element segment in the associated portion.

In Example 28, the subject matter of Example 27 can optionally include changing the resistance of each heating element segment in response to changing a chemical composition of each heating element segment.

In Example 29, the subject matter of Examples 27-28 can optionally include changing the resistance of each heating element segment in response to changing a cross sectional area of each heating element segment.

Example 30 is a thermal compression bonding heater having a non-uniform temperature pattern, the heater comprising means for positioning a die, coupled to a plurality of solder balls, over a substrate; means for heating the plurality of solder balls with a heater comprising the non-uniform temperature pattern wherein an outer portion of the die is heated to a higher temperature than an inner portion of the die; and means for compressing the die towards the substrate after the plurality of solder balls have melted.

In Example 31, the subject matter of Example 30 can optionally include wherein the means for positioning the die comprises a vacuum force.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. A method for performing a thermal compression bonding process having a non-uniform temperature pattern, the method comprising:
positioning a first apparatus, coupled to a plurality of solder balls, over a second apparatus;
heating the plurality of solder balls with a thermal compression bonding heater comprising the non-uniform temperature pattern wherein an outer portion of the first apparatus is heated to a higher temperature than an inner portion of the first apparatus; and
compressing the first apparatus towards the second apparatus after the plurality of solder balls have melted.

2. The method of claim 1 wherein heating the plurality of solder balls comprises:
heating corners of the first apparatus to a first temperature;
heating edges of the first apparatus to a second temperature; and
heating a central portion of the first apparatus to a third temperature wherein the first temperature is greater than the second temperature which is greater than the third temperature.

3. The method of claim 1 wherein heating the plurality of solder balls comprises:
heating portions of the thermal compression bonding heater associated with corners of the first apparatus to a first temperature;
heating portions of the thermal compression bonding heater associated with edges of the first apparatus to a second temperature; and
heating portions of the thermal compression bonding heater associated with a central portion of the first apparatus to a third temperature, wherein the first temperature is greater than the second temperature which is greater than the third temperature.

4. The method of claim 1 wherein heating the plurality of solder balls comprises generating a plurality of different temperatures across a surface of the thermal compression bonding heater in response to a cross sectional area of heating element segments in each portion of the thermal compression bonding heater.

5. The method of claim 1 wherein heating the plurality of solder balls comprises generating a plurality of different temperature across a surface of the thermal compression bonding heater in response to a pitch of heating element segments in each portion of the thermal compression bonding heater.

6. The method of claim 1 wherein heating the plurality of solder balls comprises generating a plurality of different temperature across a surface of the thermal compression bonding heater in response to a chemical composition of heating element segments in each portion of the thermal compression bonding heater.

7. The method of claim 1 wherein heating the plurality of solder balls comprises generating a plurality of different temperature across a surface of the thermal compression bonding heater in response to one or more of a chemical composition of heating element segments, a pitch of heating element segments, and/or a cross sectional area of heating elements segments in each portion of the thermal compression bonding heater.

8. A heater having a non-uniform temperature pattern, the heater comprising:
a plurality of heating element segments configured to generate the non-uniform temperature pattern, wherein the configuration comprises one of: a plurality of different heating element segment densities or a plurality of different heating element segment resistances.

9. The heater of claim 8 wherein the plurality of heating element segments comprise a single, continuous heating element.

10. The heater of claim 8 wherein the plurality of heating element segments comprise a plurality of discontinuous heating element segments.

11. The heater of claim 10 wherein each of the plurality of discontinuous heating element segments is configured to be powered separately from the remaining discontinuous heating element segments.

12. The heater of claim 8 wherein the heater further comprises a plurality of portions, each of the plurality of portions having a different heating element segment density of the plurality of heating element segment densities in response to a predetermined temperature to be generated by that portion.

13. The heater of claim 8 wherein the heater further comprises a plurality of portions, each of the plurality of portions comprising a heating element segment having a predetermined heating element segment resistance of the plurality of heating element segment resistances than heating element segments in other portions of the plurality of portions, the predetermined resistance determined in response to a predetermined temperature to be generated by that portion.

14. The heater of claim 8 wherein the resistance of a heating element segment is determined in response to a composition of the heating element segment.

15. The heater of claim 8 wherein the resistance of a heating element segment is determined in response to a cross sectional area of the heating element segment.

16. A heater having a non-uniform temperature pattern, the heater comprising:
a plurality of portions, each portion having a heating element segment comprising a different predetermined resistance, wherein each predetermined resistance is determined in response to a temperature to be generated by an associated portion.

17. The heater of claim 16 wherein the predetermined resistance of a first portion of the plurality of portions is determined by a composition of the heating element segment associated with the first portion.

18. The heater of claim 17 wherein the predetermined resistance of a second portion of the plurality of portions is determined by a cross sectional area of the heating element segment associated with the second portion.

19. The heater of claim 16 wherein a first portion, having a first heating element segment comprising a higher resistance than a second heating element segment in a second portion, is configured to generate a higher temperature than the second portion.

20. The heater of claim 16 wherein the heater comprises a size that is larger than a size of an integrated circuit die configured to be heated by the heater.
